(19) United States
(12) Patent Application Publication
(10) Pub. No.: US 2025/0334742 A1
(43) Pub. Date: Oct. 30, 2025

(54) COMPOSITE SUBSTRATE AND METHOD OF MANUFACTURING COMPOSITE SUBSTRATE

(71) Applicant: NGK INSULATORS, LTD., Nagoya-shi (JP)

(72) Inventors: Junji SAKAI, Gifu-shi (JP); Yuki NOMOTO, Nagoya -shi (JP); Shoichiro YAMAGUCHI, Ichinomiya -shi (JP)

(21) Appl. No.: 19/264,972

(22) Filed: Jul. 10, 2025

Related U.S. Application Data
(63) Continuation of application No. PCT/JP2024/002298, filed on Jan. 25, 2024.

(30) Foreign Application Priority Data
Jan. 27, 2023 (JP) 2023-011414

(51) Int. Cl. G02B 6/13; G02B 6/12; H10N 30/072; H10N 30/853; H10N 30/88

(52) U.S. Cl. CPC G02B 6/13; H10N 30/072; H10N 30/8542; H10N 30/88; G02B 2006/12097

(57) ABSTRACT

A composite substrate includes a piezoelectric material substrate made of an LiNbO₃ or LiTaO₃ material, a support substrate that supports the piezoelectric material substrate, and an intermediate layer provided on the support substrate, in which the piezoelectric material substrate and the support substrate are bonded to each other via the intermediate layer, the intermediate layer contains at least one of SiO₂, MgF₂, and CaF₂, and the piezoelectric material substrate includes a first layer that does not contain inert gas atoms, a second layer that is disposed on a side closer to the intermediate layer than the first layer and contains the inert gas, and a third layer that contacts the intermediate layer, and does not contain the inert gas or contains the inert gas with a lower content than the content in the second layer.

### CROSS-REFERENCE TO RELATED APPLICATION

This application is a continuation application of PCT/JP2024/002298, filed on Jan. 25, 2024, which claims the benefit of priority of Japanese Patent Application No. 2023-011414, filed on Jan. 27, 2023, the entire contents of which are incorporated herein by reference.

### 1. TECHNICAL FIELD

The present invention relates to a composite substrate and a method of manufacturing the composite substrate.

### 2. DESCRIPTION OF RELATED ART

Conventionally known is a composite substrate used for a surface acoustic wave device or the like, the composite substrate being formed by bonding a piezoelectric substrate made of a material such as lithium niobate (LiNbO₃: LN) or lithium tantalate (LiTaO₃: LT) and a support substrate made of a material such as Si. As a method of producing such a composite substrate, there has been known a method of irradiating each of bonding surfaces of the piezoelectric substrate and the support substrate with a fast atom beam (FAB) to perform activation treatment, and then directly bonding the bonding surfaces to each other. However, this method causes a reduction in bonding strength between the substrates, which may lead to separation in the processing step after the bonding.

Thus, as a technique for solving the problem, the technique of Patent Literature 1 (International Publication No. WO 2017/163722) has been known. Patent Literature 1 discloses a method of forming a film of silicon dioxide (SiO₂) as an intermediate layer on a support substrate and further forming a bonding layer made of a material such as silicon nitride (Si₃N₄) on this film to directly bonding the piezoelectric substrate and the support substrate. This method makes it possible to increase the bonding strength between the piezoelectric substrate and the support substrate to prevent separation after the bonding.

In the composite substrate having a structure in Patent Literature 1, a bonding layer made of Si₃N₄ is provided. However, when the piezoelectric substrate made of LN (LiNbO₃), LT (LiTaO₃), or the like is used as a functional layer, a composite substrate in which a bonding layer is not provided is demanded from the viewpoint of confining the energy (optical waves, acoustic waves, or the like). To obtain the composite substrate in which the bonding layer is not provided, improvement is required because the sufficient bonding strength cannot be obtained even when the piezoelectric substrate and the support substrate on which an intermediate layer of silicon dioxide is formed are bonded in a manufacturing process of the composite substrate. The same also applies to a case where the piezoelectric substrate and the support substrate are directly bonded. Therefore, there is a problem in the bonding strength between the intermediate layer provided on the support substrate or the support substrate and the piezoelectric material substrate made of an LiNbO₃ or LiTaO₃ material.

The present invention has been made in view of the above problem, and a main object of the present invention is to provide a composite substrate in which a bonding strength can be increased between an intermediate layer provided on a support substrate or a support substrate and a piezoelectric material substrate made of an LiNbO₃ or LiTaO₃ material, and a method of manufacturing the composite substrate.

### SUMMARY OF THE INVENTION

A composite substrate according to a first aspect of the present invention includes a piezoelectric material substrate made of an LiNbO₃ or LiTaO₃ material, a support substrate that supports the piezoelectric material substrate, and an intermediate layer provided on the support substrate, in which the piezoelectric material substrate and the support substrate are bonded to each other via the intermediate layer, the intermediate layer contains at least one of SiO₂, MgF₂, and CaF₂, and the piezoelectric material substrate includes a first layer that does not contain inert gas atoms, a second layer that is disposed on a side closer to the intermediate layer than the first layer and contains the inert gas, and a third layer that contacts the intermediate layer, and does not contain the inert gas or contains the inert gas with a lower content than the content in the second layer.

A composite substrate according to a second aspect of the present invention includes a piezoelectric material substrate made of an LiNbO₃ or LiTaO₃ material, and a support substrate that supports the piezoelectric material substrate and is bonded to the piezoelectric material substrate, in which the support substrate contains SiO₂, MgF₂, or CaF₂, and the piezoelectric material substrate includes a first layer that does not contain inert gas atoms, a second layer that is disposed on a side closer to the support layer than the first layer and contains the inert gas, and a third layer that contacts the support substrate, and does not contain the inert gas or contains the inert gas with a lower content than the content in the second layer.

A method of manufacturing a composite substrate according to a third aspect of the present invention includes the steps of forming an intermediate layer containing at least one of SiO₂, MgF₂, and CaF₂ on a support substrate, irradiating each of a surface of a piezoelectric material substrate formed using an LN or LT material and a surface of the intermediate layer formed on the support substrate with a fast atom beam, further irradiating the surface of the piezoelectric material surface with the fast atom beam to form a sputtered film made of the material of the piezoelectric material substrate on the surface of the intermediate layer, bonding the piezoelectric material substrate and the intermediate layer on which the sputtered film is formed to obtain a bonded body, and heating the bonded body to a predetermined temperature.

A method of manufacturing a composite substrate according to a fourth aspect of the present invention includes the steps of irradiating each of a surface of a piezoelectric material substrate formed using an LN or LT material and a surface of a support substrate containing SiO₂, MgF₂, or CaF₂ with a fast atom beam, further irradiating the surface of the piezoelectric material substrate with the fast atom beam to form a sputtered film made of the material of the piezoelectric material substrate on the surface of the support substrate, bonding the piezoelectric material substrate and the support substrate on which the sputtered film is formed to obtain a bonded body, and heating the bonded body to a predetermined temperature.

According to the present invention, it is possible to provide a composite substrate in which a bonding strength can be increased between an intermediate layer provided on a support substrate or a support substrate and a piezoelectric material substrate made of an LiNbO₃ or LiTaO₃ material, and a method of manufacturing the composite substrate.

### BRIEF DESCRIPTION OF THE DRAWINGS

FIG. 1 is a schematic cross-sectional view illustrating a schematic configuration of a composite substrate according to a first embodiment of the present invention.

FIGS. 2A, 2B, 2C and 2D are diagrams illustrating an example of a manufacturing process of the composite substrate according to the first embodiment of the present invention.

FIGS. 3E, 3F, 3G, 3H and 3I are diagrams illustrating an example of a manufacturing process of the composite substrate according to the first embodiment of the present invention.

FIG. 4 is a schematic cross-sectional view illustrating a schematic configuration of a composite substrate according to a second embodiment of the present invention.

FIGS. 5A, 5B and 5C are diagrams illustrating an example of a manufacturing process of the composite substrate according to the second embodiment of the present invention.

FIGS. 6D, 6E, 6F, 6G and 6H are diagrams illustrating an example of a manufacturing process of the composite substrate according to the second embodiment of the present invention.

FIG. 7 is a schematic cross-sectional view illustrating a schematic configuration of a composite substrate according to a third embodiment of the present invention.

FIG. 8 is a schematic cross-sectional view illustrating a schematic configuration of a composite substrate according to a fourth embodiment of the present invention.

FIGS. 9A and 9B are diagrams showing an observation photograph and EDX analysis results of Example 1.

FIGS. 10A and 10B are diagrams showing an observation photograph and EDX analysis results of Example 2.

FIGS. 11A and 11B are diagrams showing an observation photograph and EDX analysis results of a modified example of Example 1.

### DESCRIPTION OF PREFERRED EMBODIMENTS

Embodiments of the present invention will be described below with reference to the drawings. However, the present invention is not limited to these embodiments. In addition, the drawings may be schematically illustrated in terms of, for example, the width, thickness, and shape of each portion as compared to the embodiments for further clarifying the description. However, the drawings are merely examples, and do not limit the interpretation of the present invention.

### First Embodiment

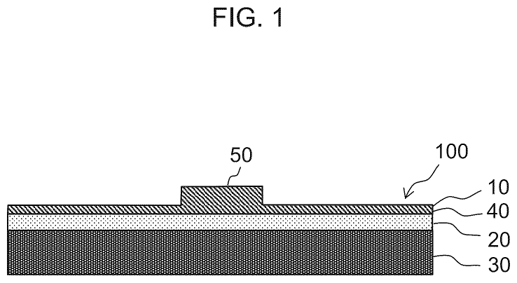

FIG. 1 is a schematic cross-sectional view illustrating a schematic configuration of a composite substrate according to a first embodiment of the present invention. A composite substrate 100 in the present embodiment is used as, for example, an optical element forming an optical waveguide, and has a structure in which a piezoelectric material substrate is bonded to a support substrate 30 via an intermediate layer 20.

In the first embodiment, the piezoelectric material substrate is a waveguide substrate 10 including an optical waveguide, and is subjected to processing (ridge processing) so that a level difference is provided in one portion of the waveguide substrate 10 to form a ridge portion 50 corresponding to the optical waveguide which has a thickness larger than the other portions. For the material of the waveguide substrate 10, a piezoelectric material such as lithium niobate (LiNbO₃: LN) or lithium tantalate (LiTaO₃: LT) is used, for example. Inside the waveguide substrate 10, a bonding interface 40 formed in a bonding step, which will be described later, is included.

The intermediate layer 20 is provided on the support substrate 30 and is disposed between the waveguide substrate 10 and the support substrate 30. For the material of the intermediate layer 20, a low refractive index material is used from the viewpoint of an effect of confining the energy, and the material of the intermediate layer 20 includes, for example, at least one of SiO₂, MgF₂ and CaF₂, and, preferably, SiO₂. Note that in a case where the support substrate 30 has a function of confining the energy by using a substrate made of SiO₂, MgF₂, or CaF₂ for the support substrate 30, the intermediate layer 20 need not be provided.

The intermediate layer 20 may be formed by any appropriate method. The layer may be formed by, for example, physical vapor deposition such as sputtering, vacuum deposition, or ion beam-assisted deposition (IAD), chemical vapor deposition, or an atomic layer deposition (ALD) method. The intermediate layer 20 can be formed at room temperature (25° C.) to 300° C., for example.

The support substrate 30 supports the waveguide substrate 10. Any appropriate substrate may be used as the support substrate 30. The support substrate 30 may include a single crystalline substance or may include a polycrystalline substance. In addition, the support substrate 30 may include metal. The waveguide substrate 10 and the support substrate 30 are bonded to each other via the intermediate layer 20.

The material forming the support substrate 30 is preferably selected from the group consisting silicon, sialon, sapphire, cordierite, mullite, glass, quartz, crystal, alumina, SUS, iron-nickel alloy (42 alloy), MgF₂, CaF₂, and brass. The thickness of the support substrate 30 is, for example, 0.3 to 1 mm, but other than the thickness, any appropriate thickness may be adopted.

The above-described silicon may be single crystalline silicon, may be polycrystalline silicon, or may be high-resistance silicon. The support substrate 30 may also be a silicon on insulator (SOI).

Typically, the above-described sialon is a ceramic obtained by sintering a mixture of silicon nitride and alumina, and has composition represented by, for example, Si₆-wAlwOwN₈-w. Specifically, the sialon has such composition that alumina is mixed into silicon nitride, and “w” in the formula represents the mixing ratio of alumina. “w” is preferably 0.5 or more and 4.0 or less.

Typically, the above-described sapphire is a single crystalline substance having the composition of Al₂O₃, and the above-described alumina is a polycrystalline substance having the composition of Al₂O₃. The alumina is preferably translucent alumina.

Typically, the above-described cordierite is a ceramic having the composition of 2Mg_{0.2}Al₂O₃·5SiO₂, and the above-described mullite is a ceramic having composition in the range of from 3Al₂O₃·2SiO₂ to 2Al₂O₃·SiO₂.

Although not illustrated, the composite substrate 100 may further include any layer. The kinds, functions, number, combination, arrangement, and the like of such layers may be appropriately set in accordance with purposes.

The composite substrate 100 may be manufactured in any appropriate shape. In one embodiment, the composite substrate 100 may be manufactured in the form of a so-called wafer. The size of the composite substrate 100 may be appropriately set in accordance with purposes, and for example, the diameter of a wafer (substrate) is from 50 mm to 150 mm.

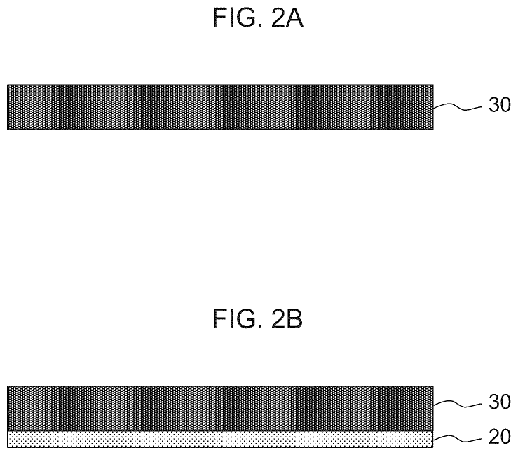

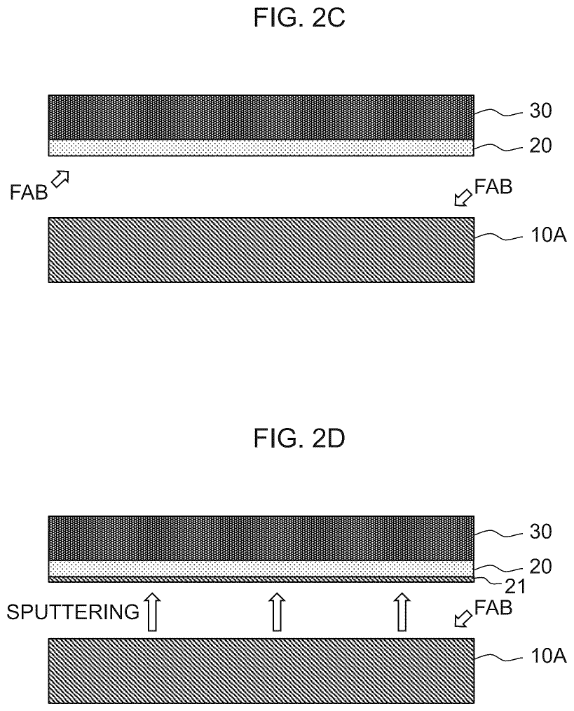

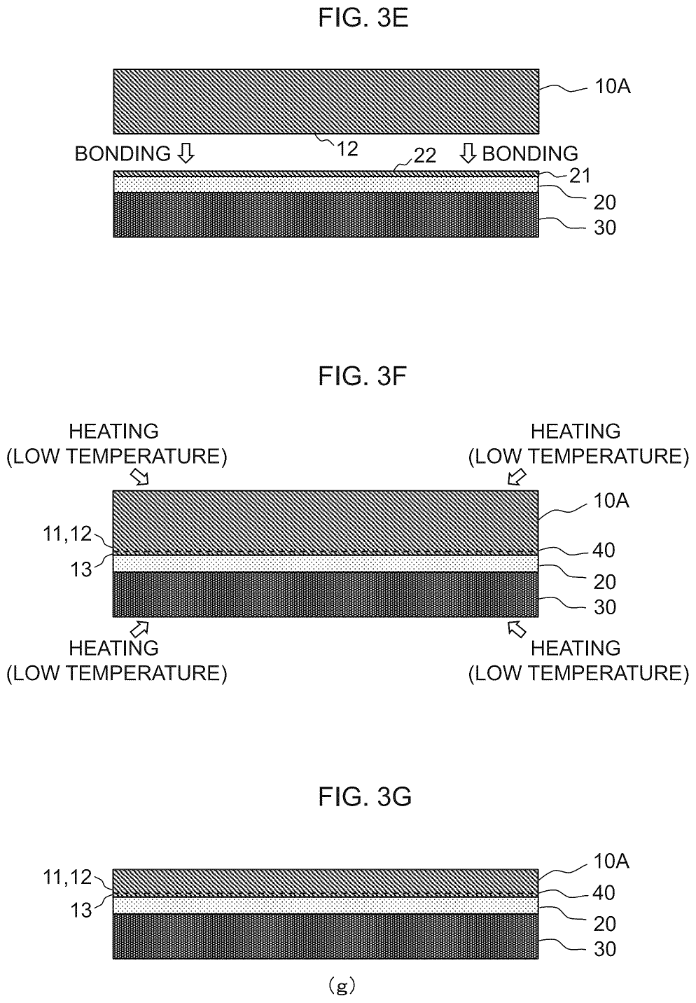

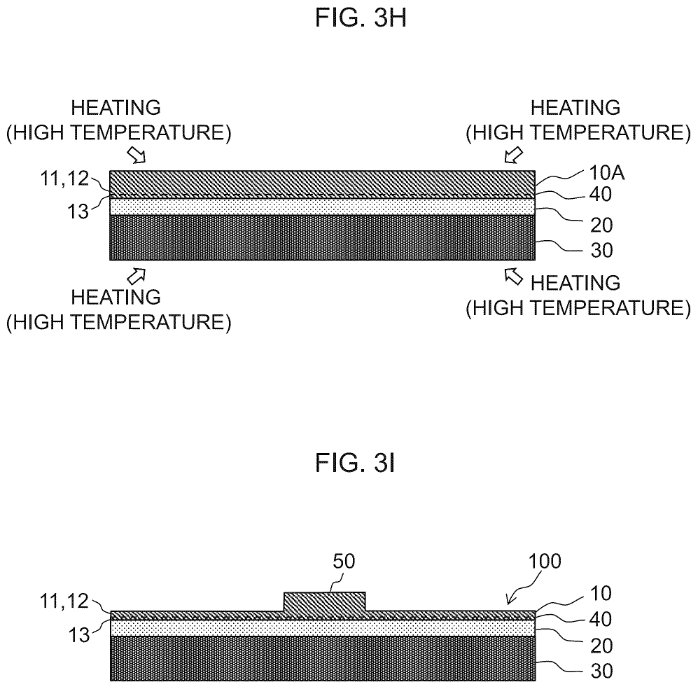

FIGS. 2A, 2B, 2C, 2D, 3E, 3F, 3G, 3H and 3I each are a diagram illustrating an example of a manufacturing process of the composite substrate according to the first embodiment of the present invention.

FIG. 2A illustrates a preparation step in the manufacturing process of the composite substrate 100. In this step, the support substrate 30 is prepared.

FIG. 2B illustrates a film formation step of the intermediate layer 20 in the manufacturing process of the composite substrate 100. In this step, for example, a film of an amorphous substance of SiO₂ is formed with a predetermined thickness on a surface of the support substrate 30 prepared in the preparation step of FIG. 2A, so that the intermediate layer 20 is formed.

FIG. 2C illustrates an activation step in the manufacturing process of the composite substrate 100. In this step, for example, an LN substrate 10A having a predetermined thickness is prepared, and the activation step is performed by irradiating, for a predetermined time, each of a surface of the intermediate layer 20 formed on the surface of the support substrate 30 in the film formation step of FIG. 2B and a surface of the LN substrate 10A with a fast atom beam (hereinafter, referred to as an FAB) in which inert gas such as Ar is used for an atomic species. At this time, the irradiation time of the FAB is preferably, for example, about 15 seconds. As described above, an LT substrate can be also used instead of the LN substrate, but in the following description, including a case where the LT substrate is used, both are collectively referred to as the “LN substrate 10A”.

FIG. 2D illustrates a sputtering step in the manufacturing process of the composite substrate 100. In this step, after each of the intermediate layer 20 and the LN substrate 10A is irradiated with the FAB in the activation step of FIG. 2C, the FAB irradiation on the intermediate layer 20 side is stopped, and the FAB irradiation on the LN substrate 10A side is continued for a further predetermined time. At this time, the FAB irradiation time is, for example, about 3 to 10 minutes, and, preferably, 4 to 7 minutes including the irradiation time in the activation step of FIG. 2C. Thus, the LN forming the LN substrate 10A is sputtered to adhere to the surface of the intermediate layer 20, and a sputtered film 21 made of the same material as the LN substrate 10A is formed on the intermediate layer 20 side.

FIG. 3E illustrates the bonding step in the manufacturing process of the composite substrate 100. In this step, the LN substrate 10A irradiated with the FAB in the activation step of FIG. 2C and the intermediate layer 20 on which the sputtered film 21 has been formed in the sputtering step of FIG. 2D are bonded to each other, so that a bonded body of the LN substrate 10A and the intermediate layer 20 are formed. Thus, the LN substrate 10A and the sputtered film 21 are bonded to be integrated, and the bonding interface 40 between the LN substrate 10A and the sputtered film 21 is formed inside the LN substrate 10A. At this time, in the LN substrate 10A, three layers (a first layer 11, a second layer 12, and a third layer 13) are formed in the vicinity of the bonding interface 40 (see FIG. 3F). The first layer 11 is a layer that does not contain inert gas atoms such as Ar irradiated as the FAB in the activation step of FIG. 2C, and the second layer 12 is a layer that is disposed on a side closer to the intermediate layer 20 than the first layer 11 and contains the above-described inert gas atoms. The third layer 13 is a layer that contacts the intermediate layer 20, and does not contain the above-described inert gas atoms or contains the above-described inert gas atoms with a lower content than that in the second layer 12. The first layer 11 is formed of a crystalline substance made of LN or LT which is a material of the LN substrate 10A, and the third layer 13 is an amorphous film obtained by amorphizing LN or LT. The second layer 12 is a crystalline substance made of LN or LT which is a material of the LN substrate 10A in the similar manner to the first layer 11, or the second layer 12 is an amorphous film obtained by amorphizing LN or LT in the similar manner to the third layer 13. These layers may contain the other atomic species that have entered the second layer 12 and the third layer 13 in the sputtering step of FIG. 2D, such as Fe atoms, Al atoms, and Cr atoms contained in a jig and a pedestal portion that are used for fixing the LN substrate 10A, for example. The details of these layers will be described later. As compared to FIGS. 2A to 2D, in FIG. 3E and onward, the positional relationship between the LN substrate 10A and the intermediate layer 20, and the support substrate 30 is vertically reversed.

FIG. 3F illustrates a preheating step in the manufacturing process of the composite substrate 100. In this step, the bonded body of the LN substrate 10A and the intermediate layer 20, which has been formed in the bonding step of FIG. 3E, is heated to a predetermined temperature. At this time, the heating temperature is lower than the heating temperature in an annealing step of FIG. 3H, which will be described later, and is preferably, for example, about 100° C., more preferably 100° C. or less. This makes it possible to increase a bonding strength between the LN substrate 10A and the intermediate layer 20 while suppressing cracks in the bonded body during heating due to a difference in thermal expansion coefficient between the LN substrate 10A and the support substrate 30. Note that the preheating step of FIG. 3F may be omitted.

FIG. 3G illustrates a thinning step in the manufacturing process of the composite substrate 100. In this step, with respect to the bonded body after being subjected to the preheating step illustrated in FIG. 3F, the LN substrate 10A is polished and thinned to a predetermined thickness. For example, the LN substrate 10A can be polished and thinned using grinding, chemical mechanical polish (CMP) processing, surface flattening processing using a gas cluster ion beam, or the like.

FIG. 3H illustrates the annealing step in the manufacturing process of the composite substrate 100. In this step, the bonded body of the LN substrate 10A thinned in the thinning step of FIG. 3G and the intermediate layer 20 is heated to a predetermined temperature. At this time, the heating temperature is higher than the heating temperature in the preheating step of FIG. 3F, and is preferably, for example, about 300 to 450° C., more preferably 400 to 450° C. This makes it possible to improve the optical propagation characteristics of the waveguide substrate 10 and reduce optical loss in the waveguide substrate 10. The reason for the improvement in the optical propagation characteristics of the waveguide substrate 10 by the annealing step will be described later. The second layer can obtain a layer comprised of a crystalline substance made of LN or LT by controlling the heating temperature in the annealing step.

Note that the inert gas atoms, and the other atomic species that have entered the second layer 12 and the third layer 13 in the above-described sputtering step may be diffused into the other layers when the LN substrate 10A is heated in the annealing step of FIG. 3H, and the degree of diffusion varies depending on the heating temperature and the heating time. That is, the contents of the Fe atoms, the Al atoms, and the Cr atoms in the first layer 11, the second layer 12, and the third layer 13 vary depending on the heating temperature and the heating time in the annealing step. Note that in the second layer and the third layer, the content of the Fe atoms is preferably 0.5 to 20 atom %, the content of the Al atoms is preferably 0.5 to 8.5 atom %, and the content of the Cr atoms is preferably 0.5 to 4.5 atom %. In addition, the content of the inert gas atoms in the second layer is preferably 2.5 to 3.5 atom %, and the content of the inert gas atoms in the third layer is preferably 0 to 1.1 atom %.

As described above, both of an increase in the bonding strength and improvement in the optical propagation characteristics can be achieved by performing the annealing step of FIG. 3H after the LN substrate 10A is thinned in the thinning step of FIG. 3G. Note that the annealing step of FIG. 3H may be omitted.

FIG. 3I illustrates a ridge processing step in the manufacturing process of the composite substrate 100. In this step, after the bonded body heated in the annealing step of FIG. 3H is cooled to room temperature, the above-described ridge processing is further performed on the LN substrate 10A that has been thinned in the thinning step of FIG. 3G, so that the ridge portion 50 functioning as the optical waveguide is formed and the waveguide substrate 10 including the optical waveguide is formed. For example, the ridge processing can be performed by processing using laser light, dry etching such as reactive ion etching (RIE), or the like.

Through the above-described steps, the composite substrate 100 having the structure illustrated in FIG. 1 is manufactured.

### Second Embodiment

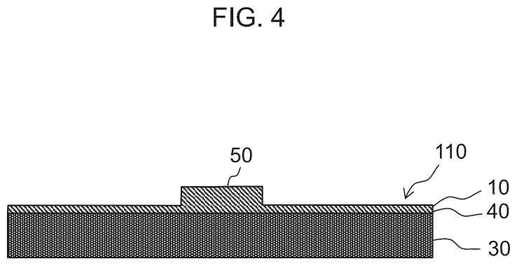

FIG. 4 is a schematic cross-sectional view illustrating a schematic configuration of a composite substrate according to a second embodiment of the present invention. A composite substrate 110 in the present embodiment has a structure different from that of the composite substrate 100 of FIG. 1 described in the first embodiment in that a waveguide substrate 10 is bonded to a support substrate 30 not via an intermediate layer 20.

As described above, in a case where the support substrate 30 has a function of confining the energy by using a substrate made of SiO₂, MgF₂, or CaF₂ for the support substrate 30, the composite substrate 110 that is usable as an optical element forming an optical waveguide can be formed without providing the intermediate layer 20 as in the structure illustrated in FIG. 4.

Note that, also in the present embodiment, the composite substrate 110 may further include any layer in a similar manner as in the first embodiment described above. The kinds, functions, number, combination, arrangement, and the like of such layers may be appropriately set in accordance with purposes. The composite substrate 110 may be manufactured in any appropriate shape in accordance with purposes.

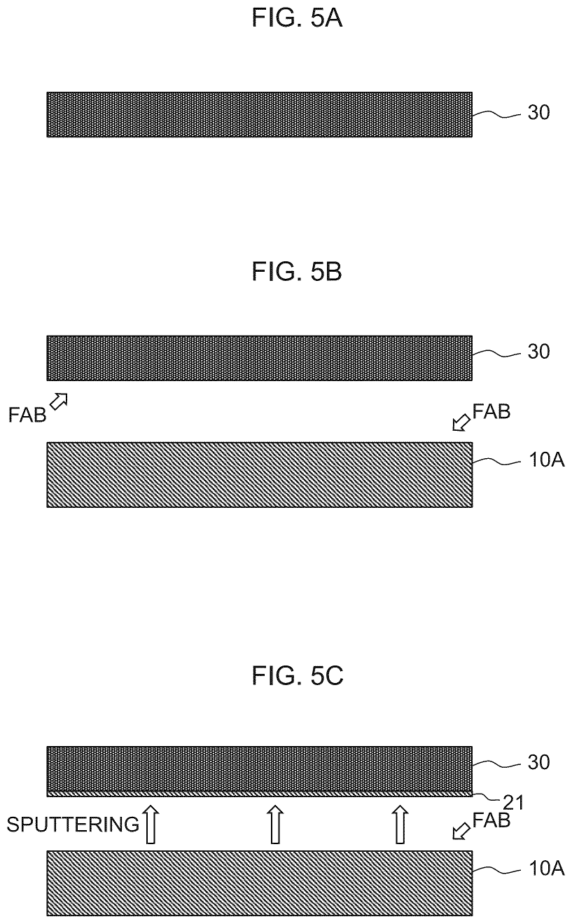

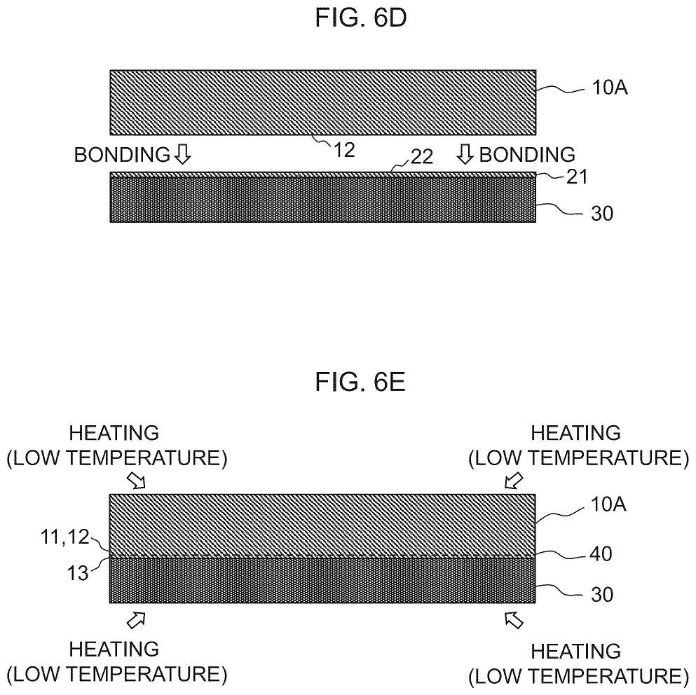

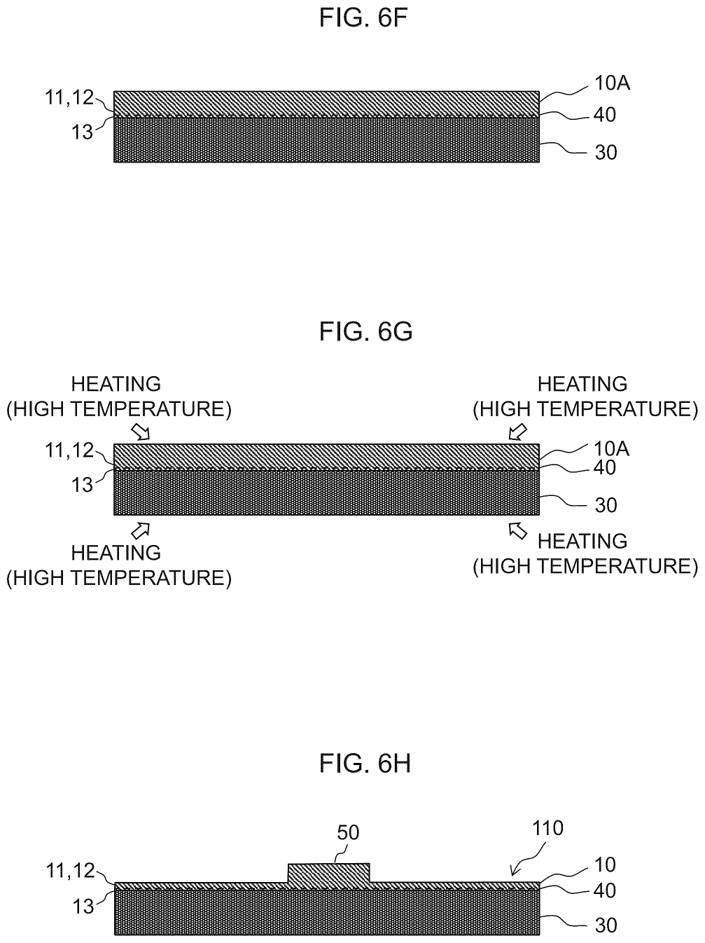

FIGS. 5A, 5B, 5C, 6D, 6E, 6F, 6G and 6H each are a diagram illustrating an example of a manufacturing process of the composite substrate according to the second embodiment of the present invention.

FIG. 5A illustrates a preparation step in the manufacturing process of the composite substrate 110. In this step, the support substrate 30 is prepared in a similar manner as in the step of FIG. 2A described in the first embodiment. Note that in the present embodiment, a step of forming the intermediate layer 20 on the support substrate 30 is omitted, unlike the first embodiment.

FIG. 5B illustrates an activation step in the manufacturing process of the composite substrate 110. In this step, for example, an LN substrate 10A having a predetermined thickness is prepared, and the activation step is performed by irradiating, for a predetermined time, each of a surface of the support substrate 30 prepared in the preparation step of FIG. 5A and a surface of the LN substrate 10A with an FAB in which inert gas such as Ar is used for an atomic species, in a similar manner as in the step of FIG. 2C described in the first embodiment.

FIG. 5C illustrates a sputtering step in the manufacturing process of the composite substrate 110. In this step, in a similar manner as in the step of FIG. 2D described in the first embodiment, after each of the support substrate 30 and the LN substrate 10A is irradiated with the FAB in the activation step of FIG. 5B, the FAB irradiation on the support substrate 30 side is stopped, and the FAB irradiation on the LN substrate 10A side is continued for a further predetermined time. At this time, the FAB irradiation time is, for example, about 3 to 10 minutes, and, preferably, 4 to 7 minutes including the irradiation time in the activation step of FIG. 5B. Thus, the LN forming the LN substrate 10A is sputtered to adhere to the surface of the support substrate 30, and a sputtered film 21 made of the same material as the LN substrate 10A is formed on the support substrate 30 side.

FIG. 6D illustrates a bonding step in the manufacturing process of the composite substrate 110. In this step, in a similar manner as in the step of FIG. 3E described in the first embodiment, the LN substrate 10A irradiated with the FAB in the activation step of FIG. 5B and the support substrate 30 on which the sputtered film 21 has been formed in the sputtering step of FIG. 5C are bonded to each other, so that a bonded body of the LN substrate 10A and the support substrate 30 are formed. Thus, the LN substrate 10A and the sputtered film 21 are bonded to be integrated, and a bonding interface 40 between the LN substrate 10A and the sputtered film 21 is formed inside the LN substrate 10A. As compared to FIGS. 5A to 5C, in FIG. 6D and onward, the positional relationship between the LN substrate 10A and the support substrate 30 is vertically reversed.

FIG. 6E illustrates a preheating step in the manufacturing process of the composite substrate 100. In this step, in a similar manner as in the step of FIG. 3F described in the first embodiment, the bonded body of the LN substrate 10A and the support substrate 30, which has been formed in the bonding step of FIG. 6D, is heated to a predetermined temperature. At this time, the heating temperature is lower than the heating temperature in an annealing step of FIG. 6G, which will be described later, and is preferably, for example, about 100° C., more preferably 100° C. or less. This makes it possible to increase a bonding strength between the LN substrate 10A and the support substrate 30 while suppressing cracks in the bonded body during heating due to a difference in thermal expansion coefficient between the LN substrate 10A and the support substrate 30, in a similar manner as in the first embodiment. Note that the preheating step of FIG. 6E may be omitted.

FIG. 6F illustrates a thinning step in the manufacturing process of the composite substrate 110. In this step, in a similar manner as in the step of FIG. 3G described in the first embodiment, with respect to the bonded body after being subjected to the preheating step illustrated in FIG. 6E, the LN substrate 10A is polished and thinned to a predetermined thickness.

FIG. 6G illustrates the annealing step in the manufacturing process of the composite substrate 110. In this step, in a similar manner as in the step of FIG. 3H described in the first embodiment, the bonded body of the LN substrate 10A thinned in the thinning step of FIG. 6F and the support substrate 30 is heated to a predetermined temperature. At this time, the heating temperature is higher than the heating temperature in the preheating step of FIG. 6E, and is preferably, for example, about 300 to 450° C., more preferably 400 to 450° C. This makes it possible to achieve both of an increase in the bonding strength and improvement in the optical propagation characteristics in a similar manner as in the first embodiment. Note that the annealing step of FIG. 6G may be omitted.

FIG. 6H illustrates a ridge processing step in the manufacturing process of the composite substrate 110. In this step, in a similar manner as in the step of FIG. 3H described in the first embodiment, after the bonded body heated in the annealing step of FIG. 6G is cooled to room temperature, the above-described ridge processing is further performed on the LN substrate 10A that has been thinned in the thinning step of FIG. 6F, so that a ridge portion 50 functioning as the optical waveguide is formed and the waveguide substrate 10 including the optical waveguide is formed.

Through the above-described steps, the composite substrate 110 having the structure illustrated in FIG. 4 is manufactured.

### Third Embodiment

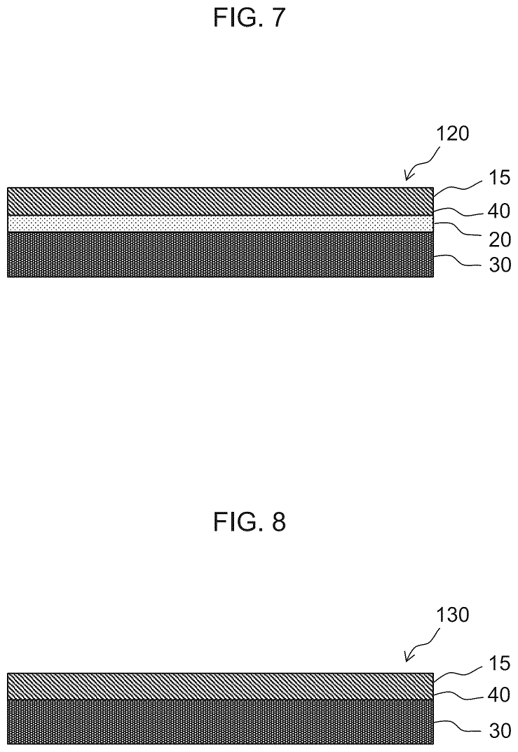

FIG. 7 is a schematic cross-sectional view illustrating a schematic configuration of a composite substrate according to a third embodiment of the present invention. A composite substrate 120 in the present embodiment is used as a piezoelectric element forming a surface acoustic wave (SAW) filter or the like, for example, and has a structure different from that of the composite substrate 100 of FIG. 1 described in the first embodiment in that a piezoelectric substrate 15 is provided instead of the waveguide substrate 10, and the piezoelectric substrate 15 is bonded to a support substrate 30 via an intermediate layer 20.

The piezoelectric substrate 15 is not subjected to the ridge processing similar to that applied to the waveguide substrate 10, and therefore does not have a ridge portion 50. For the material of the piezoelectric substrate 15, a piezoelectric material such as lithium niobate (LiNbO₃: LN) or lithium tantalate (LiTaO₃: LT) is used, for example, in a similar manner to the waveguide substrate 10. That is, the waveguide substrate 10 and the piezoelectric substrate 15 can be referred to in other words as a piezoelectric material substrate made of a piezoelectric material.

Although not illustrated, the composite substrate 120 of the present embodiment can be produced by performing the steps of FIGS. 2A to 3H described in the first embodiment. That is, by omitting the ridge processing step of FIG. 3I, the LN substrate 10A that has been polished and thinned to a predetermined thickness is used as the piezoelectric substrate 15 as it is without forming a ridge portion 50. Note that, thereafter, still other steps may be performed. Thus, inside the piezoelectric substrate 15, a bonding interface 40 is included, in a similar manner to the waveguide substrate 10. An IDT electrode is provided on a surface of the piezoelectric substrate 15 as needed.

### Fourth Embodiment

FIG. 8 is a schematic cross-sectional view illustrating a schematic configuration of a composite substrate according to a fourth embodiment of the present invention. A composite substrate 130 in the present embodiment is used as a piezoelectric element forming a surface acoustic wave (SAW) filter or the like, for example, in a similar manner to the composite substrate 120 of FIG. 7 described in the third embodiment, and has a structure different from that of the composite substrate 110 of FIG. 4 described in the second embodiment in that a piezoelectric substrate 15 is provided instead of the waveguide substrate 10, and the piezoelectric substrate 15 is bonded to a support substrate 30 not via an intermediate layer 20. Note that the material and shape of the piezoelectric substrate 15 are similar to those described in the third embodiment.

Although not illustrated, the composite substrate 130 of the present embodiment can be produced by performing the steps of FIGS. 5A to 6G described in the second embodiment. That is, by omitting the ridge processing step of FIG. 6H, the LN substrate 10A that has been polished and thinned to a predetermined thickness is used as the piezoelectric substrate 15 as it is without forming a ridge portion 50. Note that, thereafter, still other steps may be performed. Thus, inside the piezoelectric substrate 15, a bonding interface 40 is included, in a similar manner to the waveguide substrate 10. An IDT electrode is provided on a surface of the piezoelectric substrate 15 as needed.

### EXAMPLES

Examples for verifying the structure of the composite substrate according to the present invention will be specifically described below. Unless otherwise specified, the following procedure was performed at room temperature.

### Example 1

A bonded body was produced according to the described manufacturing process with reference to FIGS. 2A, 2B, 2C, 2D, 3E, 3F, 3G, 3H and 3I. Specifically, an LN substrate 10A having a diameter of 4 inches and a thickness of 500 μm and a silicon substrate were prepared and the silicon substrate was used as a support substrate 30. An amorphous substance of SiO₂ was formed with a thickness of 1.0 μm on a surface of the support substrate 30, so that an intermediate layer 20 was formed.

Next, after a surface of the LN substrate 10A and a surface of the support substrate 30 (on the intermediate layer 20 side) were washed, both substrates were introduced into a vacuum chamber, the chamber was evacuated to a level of 10⁻⁶ Pa, and each surface of both substrates was simultaneously irradiated for 15 seconds with an FAB (accelerating voltage 1 kV, Ar flow rate 27 sccm) using Ar gas. Then, the FAB irradiation on the support substrate 30 side was stopped, and the FAB irradiation on the LN substrate 10A side was further continued for 285 seconds (5 minutes in total). As a result, a sputtered film 21 was formed with a thickness of 1.1 nm on a surface of the support substrate 30 on the intermediate layer 20 side.

Next, the LN substrate 10A and the support substrate 30 were directly bonded to each other. Specifically, beam irradiation surfaces of both substrates overlapped with each other, and a pressure was applied to both substrates at 10000 N at the normal temperature for 2 minutes to bond both substrates, so that a bonded body was obtained.

Next, the obtained bonded body was placed in a high temperature furnace, and preheating was performed by increasing the temperature from room temperature to 100° C. and holding it for a certain time, and then returning it to room temperature.

Next, after the LN substrate 10A of the bonded body after preheating was ground and polished, a ridge portion 50 was formed by performing ridge processing without performing annealing so that a waveguide substrate 10 including an optical waveguide was formed, to thus obtain a composite substrate 100 having a structure illustrated in FIG. 1. At this time, no separation of a bonded portion could be confirmed during grinding and polishing. The bonding strength was evaluated by a crack opening method and found to be 2.5 J/m² or more, whereby it was confirmed that the bonding portion had a sufficient bonding strength.

The loss of the optical waveguide in the composite substrate 100 of Example 1 was measured and found to be about 13 to 15 dB/cm.

### Example 2

In a similar manner as in Example 1, a bonded body obtained in the above-described method was placed in a high temperature furnace, and preheating was performed by increasing the temperature from room temperature to 100° C. and holding it for a certain time, and then returning it to room temperature. Then, after the LN substrate 10A of the bonded body after the preheating was ground and polished, the bonded body was placed in the high temperature furnace, and the annealing was performed by increasing the temperature from room temperature to a temperature higher than 100° C. and holding it for a certain time, and then returning it to room temperature. Then, a ridge portion 50 was formed by performing ridge processing so that a waveguide substrate 10 including an optical waveguide was formed, to thus obtain a composite substrate 100 having a structure illustrated in FIG. 1. At this time, no separation of a bonded portion could be confirmed during grinding and polishing. The bonding strength was evaluated by a crack opening method and found to be 2.5 J/m² or more, whereby it was confirmed that the bonding portion had a sufficient bonding strength.

The loss of the optical waveguide in the composite substrate 100 of Example 2 was measured and found to be about 1.5 to 2 dB/cm, whereby it was confirmed that the optical propagation characteristics was improved more than Example 1.

### Example 3

In a similar manner as in Examples 1 and 2, a bonded body obtained in the above-described method was placed in a high temperature furnace, and preheating was performed by increasing the temperature from room temperature to 100° C. and holding it for a certain time, and then returning it to room temperature. Then, after the LN substrate 10A of the bonded body after the preheating was ground and polished, the bonded body was placed in the high temperature furnace, and the annealing was performed by increasing the temperature from room temperature to a temperature higher than 100° C. (temperature lower than that in Example 2) and holding it for a certain time, and then returning it to room temperature. Then, a ridge portion 50 was formed by performing ridge processing so that a waveguide substrate 10 including an optical waveguide was formed, to thus obtain a composite substrate 100 having a structure illustrated in FIG. 1. At this time, no separation of a bonded portion could be confirmed during grinding and polishing. The bonding strength was evaluated by a crack opening method and found to be 2.5 J/m² or more, whereby it was confirmed that the bonding portion had a sufficient bonding strength.

The loss of the optical waveguide in the composite substrate 100 of Example 3 was measured and found to be about 4 to 5 dB/cm, whereby it was confirmed that the value was between the value in Example 1 and the value in Example 2.

### (Structural Analysis)

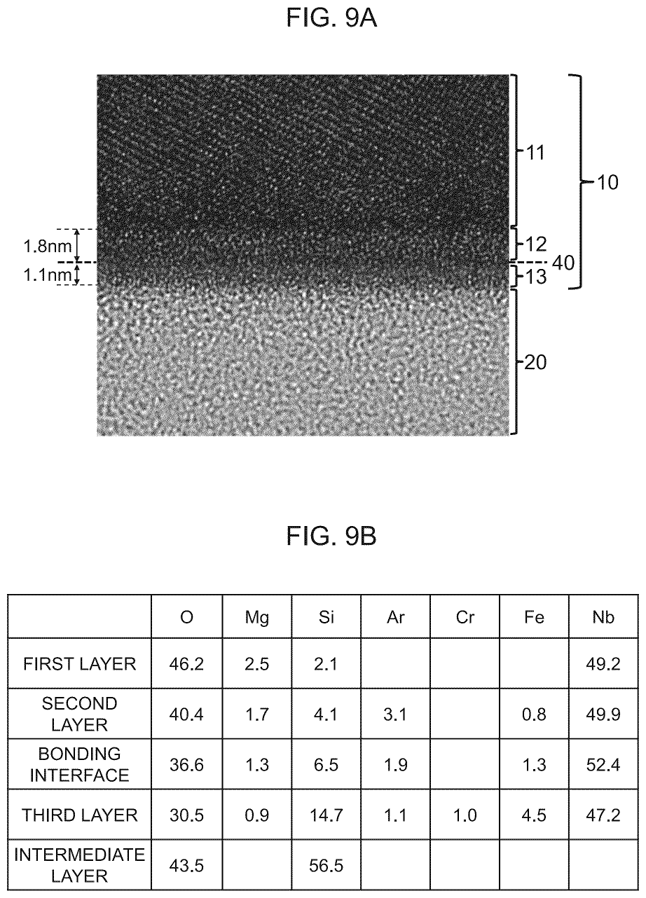

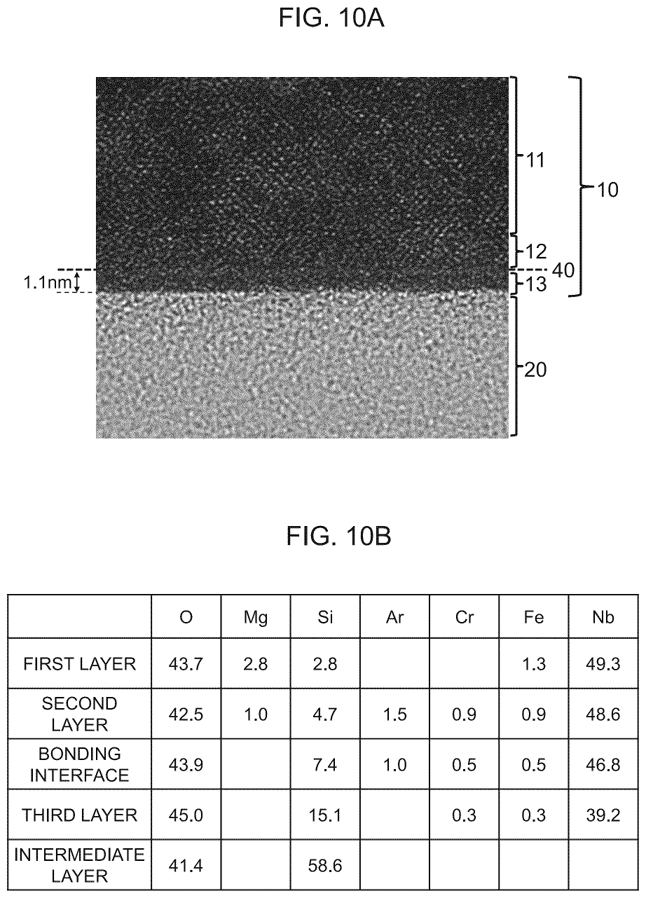

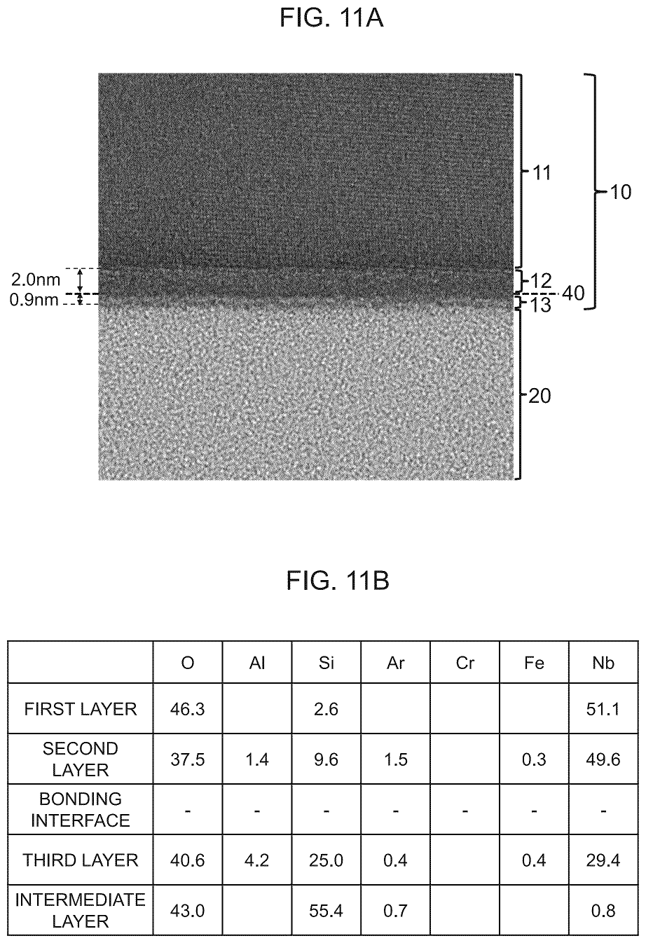

The transmission electron microscopy (TEM) observation and the EDX analysis were performed on a cross section including the bonding interface 40 of the composite substrate 100 produced in each of Examples 1 and 2, whereby the structural analysis of the composite substrate 100 was performed. FIGS. 9A and 9B show an observation photograph and EDX analysis results of Example 1, and FIGS. 10A and 10B show an observation photograph and EDX analysis results of Example 2. In addition, as a modified example of Example 1, FIGS. 11A and 11B show an observation photograph and EDX analysis results in a case where the material of a fixing structure of the LN substrate 10A was changed, in a step similar to the step in Example 1.

From the observation photograph of Example 1 shown in FIG. 9A, it is found that three layers are formed inside the waveguide substrate 10. When these layers are a first layer 11, a second layer 12, and a third layer 13 in order from the side far from the intermediate layer 20, the bonding interface 40 formed in the above-described bonding step is present between the second layer 12 and the third layer 13. The thickness of the second layer 12 was 1.8 nm, and the thickness of the third layer 13 was 1.1 nm.

As seen from the observation photograph of FIG. 9A, as compared to the first layer 11 comprised of a crystalline substance made of LN, each of the second layer 12 and the third layer 13 has no crystal structure and is comprised of an amorphous substance made of LN. That is, in Example 1, it is found that each of the second layer 12 and the third layer 13 in the waveguide substrate 10 is formed as an amorphous film obtained by amorphizing LN which is a material of the waveguide substrate 10.

The table of FIG. 9B shows ratios of element components obtained from the EDX analysis results for each of the first layer 11, the second layer 12, the bonding interface 40, the third layer 13, and the intermediate layer 20 in Example 1. However, the analysis results of the bonding interface 40 correspond to the values obtained by adding the analysis results of contact portions of the bonding interface 40 with the second layer 12 and the third layer 13.

In the table of FIG. 9B, Ar which is inert gas used for the FAB irradiation is not contained in the first layer 11, but is contained in the second layer 12 and the third layer 13. The content of Ar in the second layer 12 is higher than the content of Ar in the third layer 13. From these results, it is found that the second layer 12 corresponds to a portion of the LN substrate 10A irradiated with the FAB in the sputtering step, and the third layer 13 corresponds to the sputtered film 21 formed on the surface of the intermediate layer 20 in the sputtering step.

As seen from the table of FIG. 9B, Fe and Cr are contained in the second layer 12 and the third layer 13. This is considered to be because in the sputtering step, the FAB irradiation is performed not only on the LN substrate 10A but also on a part of the jig and the pedestal portion that are used for fixing the LN substrate 10A, and these constitutional components enter the second layer 12 and the third layer 13.

In the observation photograph of Example 2 illustrated in FIG. 10A, among the first layer 11, the second layer 12, and the third layer 13 described in FIG. 9A, the second layer 12 is recrystallized to be assimilated with the first layer 11. That is, as compared to the first layer 11 and the second layer 12 which are each comprised of a crystalline substance made of LN, the third layer 13 has no crystal structure and is comprised of an amorphous substance made of LN. Thus, in Example 2, the third layer 13 in the waveguide substrate 10 is formed as an amorphous film obtained by amorphizing LN which is a material of the waveguide substrate 10 in a similar manner to Example 1, but the second layer 12 is formed as a crystalline substance made of LN which is a material of the waveguide substrate 10, unlike Example 1.

The table of FIG. 10B shows ratios of element components obtained from the EDX analysis results for each of the first layer 11, the second layer 12, the bonding interface 40, the third layer 13, and the intermediate layer 20 in Example 2. However, the analysis results of the bonding interface 40 correspond to the values obtained by adding the analysis results of contact portions of the bonding interface 40 with the second layer 12 and the third layer 13 in a similar manner as in the table of Example 1 illustrated in FIG. 9B.

In the table of FIG. 10B, Ar which is inert gas used for the FAB irradiation is not contained in the first layer 11 and the third layer 13, but is contained in the second layer 12. The content of Ar in the second layer 12 is lower than that in Example 1. From these results, it is found that the heating temperature is high in Example 2, and thus, a part of Ar accumulated in the second layer 12 and the third layer 13 volatilizes.

From the table of FIG. 10B, it is found that Cr present in the third layer 13 in Example 1 is also contained in the second layer 12 in Example 2, and Fe present in the second layer 12 and the third layer 13 in Example 1 is also contained in the first layer 11 in Example 2. This is considered to be because the heating temperature is high in Example 2, and thus, Fe and Cr that have entered the second layer 12 and the third layer 13 are diffused.

In the observation photograph of the modified example of FIG. 11A, as compared to the first layer 11 comprised of a crystalline substance made of LN, each of the second layer 12 and the third layer 13 has no crystal structure and is comprised of an amorphous substance made of LN in a similar manner as in FIG. 9A. The bonding interface 40 formed in the above-described bonding step is present between the second layer 12 and the third layer 13. In this case, the thickness of the second layer 12 was 2.0 nm, and the thickness of the third layer 13 was 0.9 nm.

The table of FIG. 11B shows ratios of element components obtained from the EDX analysis results for each of the first layer 11, the second layer 12, the bonding interface 40, the third layer 13, and the intermediate layer 20 in the modified example.

As seen from the table of FIG. 11B, Fe and Al are contained in the second layer 12 and the third layer 13. Here, in the modified example, the LN substrate 10A was disposed on the stage made of AlN, and the activation step of FIG. 2C and the sputtering step of FIG. 2D were performed in a state in which the support substrate 30 was supported by the jig made of stainless steel. That is, as seen from the table of FIG. 11B, it is found that when the above-described stage and jig are irradiated with a part of the FAB in these steps, these constitutional components enter the second layer 12 and the third layer 13.

According to the embodiments of the present invention described above, the following operations and effects can be achieved.

(1) A composite substrate 100, 120 includes a piezoelectric material substrate (waveguide substrate 10, piezoelectric substrate 15) made of an LN (LiNbO₃) or LT (LiTaO₃) material, a support substrate 30 that supports the piezoelectric material substrate, and an intermediate layer 20 provided on the support substrate 30. The piezoelectric material substrate and the support substrate 30 contact each other via the intermediate layer 20, and the intermediate layer 20 contains at least one of SiO₂, MgF₂, and CaF₂. The piezoelectric material substrate includes a first layer 11 that does not contain inert gas atoms, a second layer 12 that is disposed on a side closer to the intermediate layer 20 than the first layer 11 and contains inert gas, and a third layer 13 that contacts the intermediate layer 20, and does not contain the inert gas or contains the inert gas with a lower content than the content in the second layer 12. This makes it possible to increase the bonding strength between the intermediate layer 20 provided on the support substrate 30 and the piezoelectric material substrate made of an LiNbO₃ or LiTaO₃ material even when the piezoelectric substrate is directly bonded to the intermediate layer 20 without providing another layer.

(2) A composite substrate 110, 130 includes a piezoelectric material substrate (waveguide substrate 10, piezoelectric substrate 15) made of an LN (LiNbO₃) or LT (LiTaO₃) material, and a support substrate 30 that supports the piezoelectric material substrate, and is bonded to the piezoelectric material substrate. The support substrate 30 contains SiO₂, MgF₂, or CaF₂. The piezoelectric material substrate includes a first layer 11 that does not contain inert gas atoms, a second layer 12 that is disposed on a side closer to the intermediate layer 20 than the first layer 11 and contains inert gas, and a third layer 13 that contacts the intermediate layer 20, and does not contain the inert gas or contains the inert gas with a lower content than the content in the second layer 12. This makes it possible to increase the bonding strength between the support substrate 30 and the piezoelectric material substrate made of an LiNbO₃ or LiTaO₃ material even when the piezoelectric material substrate is directly bonded to the support substrate 30 without providing another layer.

(3) In the composite substrate 100, 110, the piezoelectric material substrate is a waveguide substrate 10 including an optical waveguide. This makes it possible to form the composite substrate 100, 110 that is usable as an optical element forming the optical waveguide.

(4) As illustrated in FIGS. 9A, 10A, and 11A, the first layer 11 is comprised of a crystalline substance made of a material of the piezoelectric material substrate, and the third layer 13 is an amorphous film obtained by amorphizing a material of the piezoelectric material substrate. As illustrated in FIG. 10A, the second layer 12 is a crystalline substance made of a material of the piezoelectric material substrate, or as illustrated in FIGS. 9A and 11A, the second layer 12 is an amorphous film obtained by amorphizing a material of the piezoelectric material substrate. This makes it possible to provide a composite substrate 110, 110 that is excellent in the optical propagation characteristics while firmly bonding the piezoelectric material substrate and the intermediate layer 20 or the support substrate 30 by direct bonding.

(5) A bonding interface 40 that bonds the piezoelectric material substrate and the intermediate layer 20 or the support substrate 30 is formed between the second layer 12 and the third layer 13. This makes it possible to achieve bonding of the piezoelectric material substrate and the intermediate layer 20 or the support substrate 30 by directly bonding the second layer 12 and the third layer 13.

(6) Each of the second layer 12 and the third layer 13 may contain Fe atoms or Al atoms. Inert gas atoms contained in the second layer 12 and the third layer 13 may be Ar atoms. In this way, the second layer 12 and the third layer 13 are formed by the FAB irradiation, so that the composite substrate 100 to 130 can be produced.

(7) Note that the intermediate layer 20 is preferably made of SiO₂. This makes it possible to firmly bond the waveguide substrate 10 and the support substrate 30 via the intermediate layer 20.

(8) A method of manufacturing a composite substrate 100, 120 includes a film formation step of forming an intermediate layer 20 containing at least one of SiO₂, MgF₂, and CaF₂ on a support substrate 30 (FIG. 2B), an activation step of irradiating each of a surface of an LN substrate 10A formed using an LN (or LT) material and a surface of the intermediate layer 20 formed on the support substrate 30 with an FAB (FIG. 2C), a sputtering step of further irradiating the surface of the LN substrate 10A with the FAB to form a sputtered film 21 made of the material of the LN substrate 10A on the surface of the intermediate layer 20 (FIG. 2D), a bonding step of bonding the LN substrate 10A and the intermediate layer 20 on which the sputtered film 21 is formed to obtain a bonded body (FIG. 3E), and a preheating step (FIG. 3F) and/or an annealing step (FIG. 3H) of heating the bonded body to a predetermined temperature. At this time, the FAB irradiation time with respect to the surface of the LN substrate 10A is 3 to 10 minutes in total, and the predetermined temperature during heating in the annealing step is preferably 300 to 450° C. In this way, the composite substrate 100, 120 can be produced.

(9) A method of manufacturing a composite substrate 110, 130 includes an activation step of irradiating each of a surface of an LN substrate 10A formed using an LN (or LT) material and a surface of a support substrate 30 containing SiO₂, MgF₂, or CaF₂ with an FAB (FIG. 5B), a sputtering step of further irradiating the surface of the LN substrate 10A with the FAB to form a sputtered film 21 made of the material of the LN substrate 10A on the surface of the support substrate 30 (FIG. 5C), a bonding step of bonding the LN substrate 10A and the support substrate 30 on which the sputtered film 21 is formed to obtain a bonded body (FIG. 6D), and a preheating step (FIG. 6E) and/or an annealing step (FIG. 6G) of heating the bonded body to a predetermined temperature. At this time, the FAB irradiation time with respect to the surface of the LN substrate 10A is 3 to 10 minutes in total, and the predetermined temperature during heating in the annealing step is preferably 300 to 450° C. In this way, the composite substrate 110,130 can be produced.

(10) The method of manufacturing the composite substrate 100 to 130 may further include a thinning step of polishing to thin the LN substrate 10A after the bonded body is heated to a first predetermined temperature in the preheating step (FIGS. 3G and 6F), and an annealing step of heating the bonded body in which the LN substrate 10A is thinned in the thinning step, to a second predetermined temperature higher than the first predetermined temperature. At this time, the first predetermined temperature at which the bonded body is heated in the preheating step is preferably 100° C. or less, and the second predetermined temperature at which the bonded body is heated in the annealing step is preferably 300 to 450° C. In this way, the composite substrate 100 to 130 can be produced which can achieve both an increase in the bonding strength and improvement in the optical propagation characteristics.

Note that the present invention is not limited to the above-described embodiments, and can be implemented using any component without departing from the scope and sprit of the present invention.

The above-described embodiments and modified example are merely an example, and the present invention is not limited to these contents within a range that does not impair the characteristics of the invention. Various embodiments and modified example have been described above, but the present invention is not limited to these contents. Other modes that are considered to fall within the range of the technical concept of the present invention are also included within the scope of the present invention.

What is claimed is:

1. A composite substrate, comprising:
a piezoelectric material substrate made of an LiNbO₃ or LiTaO₃ material;
a support substrate that supports the piezoelectric material substrate; and
an intermediate layer provided on the support substrate,
wherein the piezoelectric material substrate and the support substrate are bonded to each other via the intermediate layer,
the intermediate layer contains at least one of SiO₂, MgF₂, and CaF₂, and
the piezoelectric material substrate includes a first layer that does not contain inert gas atoms, a second layer that is disposed on a side closer to the intermediate layer than the first layer and contains the inert gas, and a third layer that contacts the intermediate layer, and does not contain the inert gas or contains the inert gas with a lower content than the content in the second layer.

2. A composite substrate, comprising:
a piezoelectric material substrate made of an LiNbO₃ or LiTaO₃ material; and
a support substrate that supports the piezoelectric material substrate and is bonded to the piezoelectric material substrate,
wherein the support substrate contains SiO₂, MgF₂, or CaF₂, and
the piezoelectric material substrate includes a first layer that does not contain inert gas atoms, a second layer that is disposed on a side closer to the support substrate than the first layer and contains the inert gas, and a third layer that contacts the support substrate, and does not contain the inert gas or contains the inert gas with a lower content than the content in the second layer.

3. The composite substrate according to claim 1, wherein
the piezoelectric material substrate is a waveguide substrate including an optical waveguide.

4. The composite substrate according to claim 2, wherein
the piezoelectric material substrate is a waveguide substrate including an optical waveguide.

5. The composite substrate according to claim 1, wherein
the first layer is comprised of a crystalline substance made of a material of the piezoelectric material substrate, and
the third layer is an amorphous film obtained by amorphizing a material of the piezoelectric material substrate.

6. The composite substrate according to claim 2, wherein
the first layer is comprised of a crystalline substance made of a material of the piezoelectric material substrate, and
the third layer is an amorphous film obtained by amorphizing a material of the piezoelectric material substrate.

7. The composite substrate according to claim 5, wherein
the second layer is a crystalline substance made of a material of the piezoelectric material substrate.

8. The composite substrate according to claim 6, wherein
the second layer is a crystalline substance made of a material of the piezoelectric material substrate.

9. The composite substrate according to claim 5, wherein
the second layer is an amorphous film obtained by amorphizing a material of the piezoelectric material substrate.

10. The composite substrate according to claim 6, wherein
the second layer is an amorphous film obtained by amorphizing a material of the piezoelectric material substrate.

11. The composite substrate according to claim 1, wherein
a bonding interface that bonds the piezoelectric material substrate and the intermediate layer is formed between the second layer and the third layer.

12. The composite substrate according to claim 2, wherein
a bonding interface that bonds the piezoelectric material substrate and the support substrate is formed between the second layer and the third layer.

13. The composite substrate according to claim 1, wherein
each of the second layer and the third layer contains Fe atoms.

14. The composite substrate according to claim 2, wherein
each of the second layer and the third layer contains Fe atoms.

15. The composite substrate according to claim 1, wherein
each of the second layer and the third layer contains Al atoms.

16. The composite substrate according to claim 2, wherein
each of the second layer and the third layer contains Al atoms.

17. The composite substrate according to claim 1, wherein
the inert gas atoms are Ar atoms.

18. The composite substrate according to claim 2, wherein
the inert gas atoms are Ar atoms.

19. The composite substrate according to claim 1, wherein
the intermediate layer is made of SiO₂.

20. A method of manufacturing a composite substrate, comprising the steps of:
forming an intermediate layer containing at least one of SiO₂, MgF₂, and CaF₂ on a support substrate;
irradiating each of a surface of a piezoelectric material substrate formed using an LN or LT material and a surface of the intermediate layer formed on the support substrate with a fast atom beam;
further irradiating the surface of the piezoelectric material substrate with the fast atom beam to form a sputtered film made of the material of the piezoelectric material substrate on the surface of the intermediate layer;
bonding the piezoelectric material substrate and the intermediate layer on which the sputtered film is formed to obtain a bonded body; and
heating the bonded body to a predetermined temperature.

21. A method of manufacturing a composite substrate, comprising the steps of:
irradiating each of a surface of a piezoelectric material substrate formed using an LN or LT material and a surface of a support substrate containing SiO₂, MgF₂, or CaF₂ with a fast atom beam;
further irradiating the surface of the piezoelectric material substrate with the fast atom beam to form a sputtered film made of the material of the piezoelectric material substrate on the surface of the support substrate;
bonding the piezoelectric material substrate and the support substrate on which the sputtered film is formed to obtain a bonded body; and
heating the bonded body to a predetermined temperature.

22. The method of manufacturing a composite substrate according to claim 20, wherein
an irradiation time of the fast atom beam with respect to the surface of the piezoelectric material substrate is 3 to 10 minutes in total.

23. The method of manufacturing a composite substrate according to claim 21, wherein
an irradiation time of the fast atom beam with respect to the surface of the piezoelectric material substrate is 3 to 10 minutes in total.

24. The method of manufacturing a composite substrate according to claim 20, wherein
the predetermined temperature is 300 to 450° C.

25. The method of manufacturing a composite substrate according to claim 21, wherein
the predetermined temperature is 300 to 450° C.

26. The method of manufacturing a composite substrate according to claim 20, further comprising the steps of:
polishing to thin the piezoelectric material substrate after the bonded body is heated to a first predetermined temperature; and
heating the bonded body in which the piezoelectric material substrate is thinned, to a second predetermined temperature higher than the first predetermined temperature.

27. The method of manufacturing a composite substrate according to claim 21, further comprising the steps of:
polishing to thin the piezoelectric material substrate after the bonded body is heated to a first predetermined temperature; and
heating the bonded body in which the piezoelectric material substrate is thinned, to a second predetermined temperature higher than the first predetermined temperature.

28. The method of manufacturing a composite substrate according to claim 26, wherein
the first predetermined temperature is 100° C. or less, and
the second predetermined temperature is 300 to 450° C.

29. The method of manufacturing a composite substrate according to claim 27, wherein
the first predetermined temperature is 100° C. or less, and
the second predetermined temperature is 300 to 450° C.
